(19) United States
(12) Patent Application Publication
(10) Pub. No.: US 2024/0396502 A1
(43) Pub. Date: Nov. 28, 2024

(54) SINGLE-ENDED-TO-DIFFERENTIAL TRANSCONDUCTANCE AMPLIFIERS AND APPLICATIONS THEREOF

(71) Applicant: NORDIC SEMICONDUCTOR ASA, Trondheim (NO)

(72) Inventors: Jarkko JUSSILA, Oulu (FI); Pete SIVONEN, Oulu (FI)

(21) Appl. No.: 18/696,235

(22) PCT Filed: Sep. 28, 2022
(86) PCT No.: PCT/EP2022/077020

§ 371 Date: Mar. 27, 2024

(30) Foreign Application Priority Data
Sep. 29, 2021 (FI) 20216009

(51) Int. Cl. H03F 1/22; H03F 1/26; H03F 3/26; H03F 3/45

(52) U.S. Cl. CPC H03F 1/223; H03F 1/26; H03F 3/265; H03F 3/45475; H03F 2200/294; H03F 2200/451; H03F 2203/45526

(57) ABSTRACT

According to an aspect, there is provided a single-ended-to-differential complementary metal-oxide-semiconductor, SE2D CMOS, transconductance amplifier for a radio receiver. The SE2D CMOS transconductance amplifier comprises an input for receiving a radio frequency signal, first common-source n-type metal-oxide-semiconductor. CS NMOS (M₁), and common-source p-type metal-oxide-semiconductor, CS PMOS, transistors (M₅), second CS NMOS (M₂) and CS PMOS (M₆) transistors, a cross-coupled cascode stage for adjusting balance of the radio frequency currents outputted by the first (M₁) and second (M₂) CS NMOS transistors and a differential output. The first (M₁) and second (M₂) CS NMOS transistors have substantially equal transconductances and the first (M₅) and second (M₆) CS PMOS transistors have substantially equal transconductances. The first and second cross-coupled cascode NMOS transistors have substantially equal transconductances.

### TECHNICAL FIELD

Various example embodiments relate to single-ended-to-differential conversion in radio receivers and transceivers.

### BACKGROUND

Integration of radio frequency (RF) transceivers on system-on-chips (SoC) possesses challenges, which relate to the isolation of sensitive analog and RF victim circuits for example from noisy digital and power management aggressor circuits. Since balanced analog and RF circuit architectures are able to reject common-mode interference for instance from supply lines and common substrate and, thus, improve the isolation between sensitive victim and aggressor circuitry, balanced analog circuit topologies are preferred in SoCs. For instance, digital circuits and crystal oscillator (XO) may produce clock signal harmonics at wide band of RF frequencies and this may corrupt the reception of the weak RF signal in the radio receiver. This may happen due to the fact that the clock harmonics appear directly at the reception band. In balanced circuit topologies, clock harmonics and other spurious signals often couple in common mode meaning that they are ideally rejected in differential signal processing. Differential circuits also generate less even-order distortion compared to their single-ended counterparts and for example double-balanced mixers provide better port-to-port isolation compared to the single-balanced mixers.

Although balanced or differential circuit topologies are usually preferred in modern radio receivers (and transmitters), the antenna of the radio receiver is typically a single-ended element meaning that a single-ended-to-differential (SE2D) conversion is needed after the antenna in the receiver chain. One alternative for performing SE2D conversion is to employ a transformer between the (single-ended) RF preselection filter and low-noise amplifier (LNA). However, the transformer is an additional component and it thus increases cost and bills-of-material (BOM). Moreover, transformers have finite loss which increases the receiver noise figure (NF).

Modern wireless terminal devices employ cellular, such as 3G, 4G, or long term evolution (LTE), chipsets with RF transceivers, which need to support large number of frequency bands covering different areas and countries. Accordingly, in multiband wireless receivers, multiple RF preselection filters and transformers are also needed, assuming that transformers are employed to perform the SE2D conversion. This requirement of multiple transformers increases cost and BOM even further. In addition, if the SE2D transformation is performed either by a RF preselection filter or a transformer, the LNAs need to have differential inputs. In multiband receivers, however, the requirement of having differential LNA input pins increases inevitably the total number of LNA input pins needed on the radio frequency integrated circuit (RFIC) and the cost of RFIC itself as well as making the routing on printed-circuit board (PCB) more complicated. In other words, preferably the LNA would have a single-ended input and the SE2D conversion would be performed on the RFIC.

Thus, there is a need for a solution for performing the SE2D conversion in a manner which overcomes the aforementioned problems while still providing satisfactory performance.

### BRIEF DESCRIPTION

According to a first aspect, there is provided a single-ended-to-differential transconductance complementary metal-oxide-semiconductor, SE2D CMOS, amplifier for a radio receiver. The SE2D CMOS transconductance amplifier comprises:
an input for receiving a radio frequency, RF, signal;
first common-source n-type metal-oxide-semiconductor, CS NMOS, and common-source p-type metal-oxide-semiconductor, CS PMOS, transistors, wherein
   a gate of the first CS NMOS transistor is coupled to the input directly or via a first capacitor and
   a gate of the first CS PMOS transistor is coupled to the input directly or via a fifth capacitor;
second CS NMOS and CS PMOS transistors, wherein
   a gate of the second CS NMOS transistor is coupled to a drain of the first CS NMOS transistor directly or via a second capacitor,
   a gate of the second CS PMOS transistor is coupled to the drain of the first CS NMOS transistor directly or via a sixth capacitor,
   the first and second CS NMOS transistors have substantially equal transconductances and
   the first and second CS PMOS transistors have substantially equal transconductances;
a cross-coupled cascode stage comprising first and second cross-coupled cascode NMOS transistors having substantially equal transconductances, wherein
   a drain of the first cross-coupled cascode NMOS transistor is coupled directly to a drain of the first CS PMOS transistor,
   a source of the first cross-coupled cascode NMOS transistor is coupled directly to the drain of the first CS NMOS transistor,
   a gate of the first cross-coupled cascode NMOS transistor is coupled via a fourth capacitor to a source of the second cross-coupled cascode NMOS transistor,
   a drain of the second cross-coupled cascode NMOS transistor is coupled directly to a drain of the second CS PMOS transistor,
   a source of the second cross-coupled cascode NMOS transistor is coupled directly to a drain of the second CS NMOS transistor and
   a gate of the second cross-coupled cascode NMOS transistor is coupled via a third capacitor to a source of the first cross-coupled cascode NMOS transistor; and
a differential output having a positive terminal provided between the drains of the second CS PMOS transistor and the second cross-coupled cascode NMOS transistor and a negative terminal provided between the drains of the first CS PMOS transistor and the first cross-coupled cascode NMOS transistor.

According to a second aspect, there is provided a single-ended-to-differential bipolar junction transistor, SE2D BJT, transconductance amplifier for a radio receiver. The SE2D BJT transconductance amplifier comprises:
an input for receiving a radio frequency, RF, signal;
first common-emitter, CE, NPN and CE PNP transistors, wherein
   a base of the first CE NPN transistor is coupled to the input directly or via a first capacitor and
   a base of the first CE PNP transistor is coupled to the input directly or via a fifth capacitor;
second CE NPN and CE PNP transistors, wherein
   a base of the second CE NPN transistor is coupled to a collector of the first CE NPN transistor directly or via a second capacitor,
   a base of the second CE PNP transistor is coupled to the collector of the first CE NPN transistor directly or via a sixth capacitor,
   the first and second CE NPN transistors have substantially equal transconductances and
   the first and second CE PNP transistors have substantially equal transconductances;
a cross-coupled cascode stage comprising first and second cross-coupled cascode NPN transistors having substantially equal transconductances, wherein
   a collector of the first cross-coupled cascode NPN transistor is coupled directly to a collector of the first CE PNP transistor,
   an emitter of the first cross-coupled cascode NPN transistor is coupled directly to the collector of the first CE NPN transistor,
   a base of the first cross-coupled cascode NPN transistor is coupled via a fourth capacitor to an emitter of the second cross-coupled cascode NPN transistor,
   a collector of the second cross-coupled cascode NPN transistor is coupled directly to a collector of the second CE PNP transistor,
   an emitter of the second cross-coupled cascode NPN transistor is coupled directly to a collector of the second CE NPN transistor and
   a base of the second cross-coupled cascode NPN transistor is coupled via a third capacitor to an emitter of the first cross-coupled cascode NPN transistor; and
a differential output having a positive terminal provided between the collectors of the second CE PNP transistor and the second cross-coupled cascode NPN transistor and a negative terminal provided between the collectors of the first CE PNP transistor and the first cross-coupled cascode NPN transistor.

Both of the first and second aspects provide the technical effect that simultaneous single-ended-to-differential conversion is carried out using active devices in a manner which serves to minimize use of silicon area on a chip while ensuring high signal quality.

Both of the first and second aspects provide the advantage that silicon area on a chip needed for the SE2D CMOS/BJT amplifier is small, compared to, e.g., conventional SE2D CMOS/BJT amplifiers relying on integrated passive magnetic transformers. Also in contrast to said conventional SE2D CMOS/BJT amplifiers, the SE2D CMOS/BJT amplifier according to the first/second aspect is less sensitive to picking up interference and spurious signals, such as clock harmonics at RF, leading to an improved signal quality.

Embodiments are defined in the dependent claims. The scope of protection sought for various embodiments is set out by the independent claims.

The embodiments and features, if any, described in this specification that do not fall under the scope of the independent claims are to be interpreted as examples useful for understanding various embodiments of the invention.

### BRIEF DESCRIPTION OF DRAWINGS

In the following, example embodiments will be described in greater detail with reference to the attached drawings, in which

FIG. 1 illustrates a direct-conversion radio receiver architecture with a single-ended-to-differential transconductance amplifier according to embodiments;

FIG. 2 illustrates a CMOS-based single-ended-to-differential transconductance amplifier according to embodiments;

FIG. 3 illustrates a CMOS-based single-ended-to-differential transconductance amplifier according to embodiments with added notations for facilitating analyzing its operation;

FIGS. 4A and 4B illustrate biasing schemes for a CMOS-based single-ended-to-differential transconductance amplifier according to embodiments;

FIGS. 5A, 5B and 5C illustrate a direct-conversion radio receiver architecture comprising a single-ended-to-differential resistive-feedback CMOS LNA according to embodiments, said single-ended-to-differential resistive-feedback CMOS LNA in more detail and said single-ended-to-differential resistive-feedback CMOS LNA with a differential load resistor, respectively;

FIGS. 6A, 6B and 6C illustrate a direct-conversion radio receiver architecture comprising a single-ended-to-differential capacitive-feedback CMOS LNA according to embodiments, said single-ended-to-differential capacitive-feedback CMOS LNA in more detail and said single-ended-to-differential capacitive feedback CMOS LNA with a differential load capacitor, respectively; and

FIG. 7 illustrates a BJT-based single-ended-to-differential transconductance amplifier according to embodiments.

### DETAILED DESCRIPTION OF SOME EMBODIMENTS

The following embodiments are only presented as examples. Although the specification may refer to “an”, “one”, or “some” embodiment(s) and/or example(s) in several locations of the text, this does not necessarily mean that each reference is made to the same embodiment(s) or example(s), or that a particular feature only applies to a single embodiment and/or example. Single features of different embodiments and/or examples may also be combined to provide other embodiments and/or examples.

In the following, the expression “connected” or “connected directly” or “coupled” or “coupled directly” as used in connection with circuit elements may be defined to mean a direct electrical connection, that is, that a connection by means of a conducting path exists between the elements. These expressions may, thus, correspond to direct coupling (equally called direct current, DC, coupling).

On the other hand, the expression “coupled via a capacitor” or equally “connected via a capacitor” explicitly defines that DC is blocked, i.e., that the associated elements are capacitively coupled or equally alternating current (AC)-coupled.

As described above at length, a single-ended-to-differential (SE2D) conversion needs to be performed in most modern radio receivers after the antenna in the receiver chain due to the fact that the antenna of the radio receiver is typically single-ended while balanced or differential circuit topologies are usually preferred in other parts of the radio receiver.

Most of the modern radio receivers also employ current-mode passive mixers as down-conversion mixers. Current-mode passive mixers have the benefits of being essentially free of flicker noise and providing excellent linearity at low supply voltage. The current-mode passive mixer is ideally driven by a voltage-to-current amplifier or transconductance amplifier (or simply transconductor) which ideally has large input and output impedances. Large input (or output) impedance may be defined, here and in the following, as being at least 10 times larger than the output (or input) impedance of the preceding (or following) block. The current-mode mixer is ideally followed by a current-buffer or transimpedance amplifier (TIA) which ideally has small input impedance. Small input impedance here simply means that it is preferably at least 10 times lower than the output impedance of the preceding block.

It would be possible to perform the SE2D conversion in such a radio receiver using current-mode passive mixers with an integrated passive transformer connected between the single-ended LNA and double-balanced down conversion mixer. However, the performance of truly single-ended LNAs, i.e., LNAs having both single-ended input and output, are sensitive to parasitic ground and supply impedances making this solution less than ideal. In addition, a single-ended LNA would be sensitive to clock harmonics and other spurious signals on the integrated circuit (IC).

According to embodiments, it is suggested to perform the SE2D conversion with active devices or with a SE2D transconductance amplifier, instead of, e.g., employing said passive transformer between the single-ended LNA and the double-balanced mixer. This leads to lower cost and silicon area, since integrated passive magnetic transformers consume large silicon area. Also, integrated passive magnetic transformers may also pick up interference and spurious signals, such as clock harmonics at RF, magnetically. This detrimental behavior is avoided when using the solutions according to embodiments.

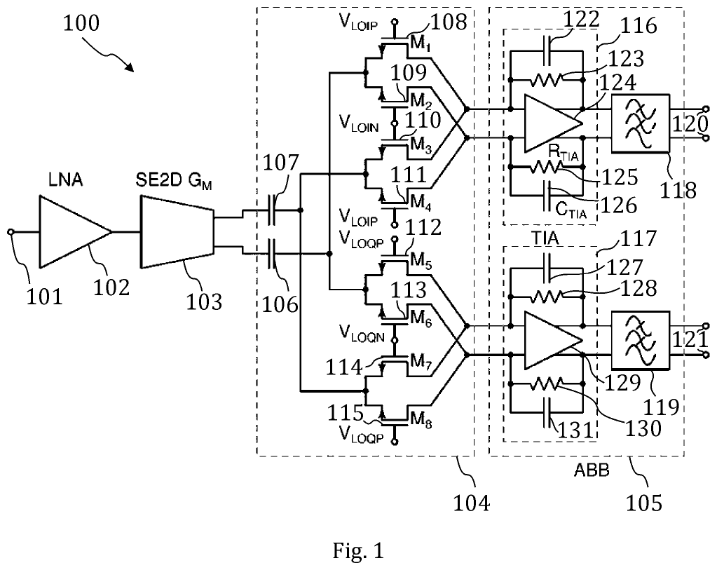

FIG. 1 illustrates a direct-conversion radio receiver architecture 100 with a SE2D transconductance amplifier according to embodiments. Specifically, the radio receiver architecture corresponds to a multiband direct conversion or zero intermediate frequency (zero-IF) radio receiver using IQ demodulation. The radio receiver architecture of FIG. 1 may form a part of a radio transceiver (not shown in FIG. 1). The radio receiver 100 may be comprised, for example, in a user device (or a terminal device) or in an access or relay node. It should be noted that FIG. 1 shows only some of the elements of a radio receiver 100 which are of relevance in view of the embodiments.

As the embodiments to be discussed below may be specifically implemented in the radio receiver 100 (specifically as the element 103 thereof), the operation of the radio receiver 100 is discussed briefly in the following for completeness of presentation. It should, however, be noted that the embodiments of the SE2D transconductance amplifier are not restricted to be used only in connection with the radio receiver 100 given as an example but a person skilled in the art may apply the solution to other radio receivers or transceivers provided with necessary properties or to other radio devices requiring SE2D conversion.

Referring to FIG. 1, the radio receiver comprises an LNA 102, a SE2D transconductance amplifier (SE2D G_{M}) 103, a current-mode passive IQ mixer 104 and an analog baseband (ABB) circuitry 105 (listed in the order of signal reception in the RF chain of the radio receiver 100). The port or terminal 101 corresponds to an RF input port or terminal while the two differential ports or terminals 120, 121 correspond to baseband differential in-phase (I) and quadrature (Q) signal outputs. The input terminal 101 may be connected (optionally via one or more circuit elements such as a RF preselection filter for filtering out blocking signals from the received RF signal) to at least one antenna for receiving radio signals (not shown in FIG. 1), similar to any conventional radio receiver. The at least one antenna used for receiving or capturing the RF signal propagating in free space (e.g., in air) may be of any known antenna type configured to operate at one or more operational frequency bands of the radio receiver 100. The two differential terminals 120, 121 may be connected, e.g., at least to an analog-to-digital (ADC) converter of the radio receiver 100 and further to digital circuitry of the radio receiver 100 for performing digital signal processing (not shown in FIG. 1), similar to any conventional RF receiver.

All the elements illustrated in FIG. 1 may be so-called on-chip elements (i.e., elements implemented in an integrated circuit). Said at least one antenna and the RF preselection filter (if one is included in the radio receiver) mentioned above (though not shown in FIG. 1) may, however, be off-chip elements (i.e., elements not implemented in an integrated circuit).

The LNA 102 is used for amplifying the RF signal received at least via said at least one antenna. The LNA 102 may be any conventional low-noise amplifier. Said LNA 102 may be specifically configured to operate at a plurality of operating frequency bands of the radio receiver 100.

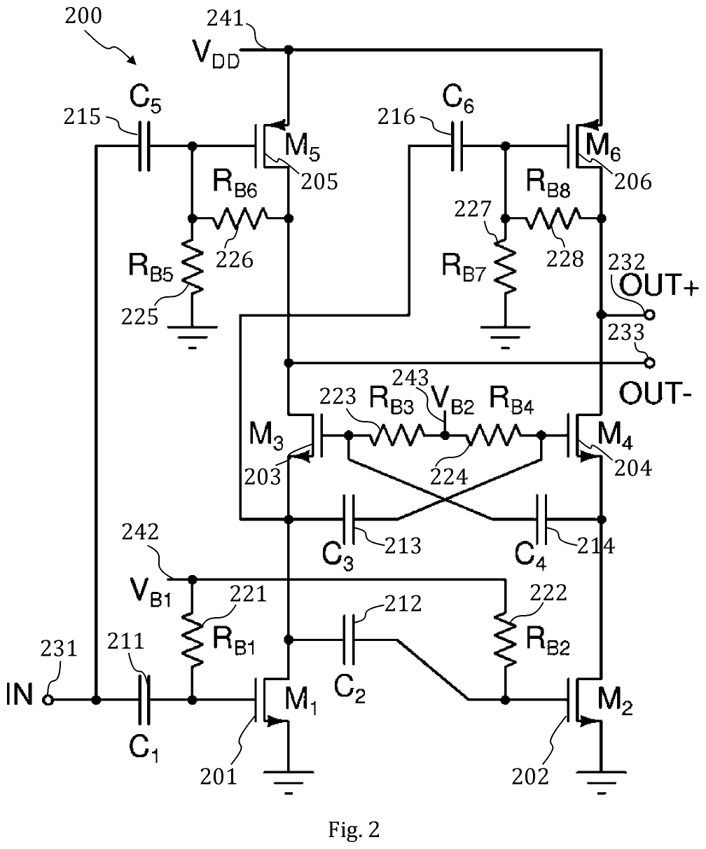

The SE2D transconductance amplifier 103 which drives the current-mode passive IQ mixer 104 may be specifically an SE2D transconductance complementary metal-oxide-semiconductor (CMOS) amplifier. The circuit topology of the SE2D CMOS transconductance amplifier according to embodiments is discussed in detail in connection with FIG. 2.

The current-mode passive IQ mixer 104 is configured to mix received amplified RF signal with in-phase (0°) and quadrature (90°) local oscillator signals (inputted via terminals V_{LOIP}, V_{LOIN}, V_{LOQP} and V_{LOQN}). In FIG. 1, a typical circuit topology of a current-mode passive IQ mixers is shown with elements 106 to 115.

Specifically, the current-mode passive IQ mixer 104 comprises two double-balanced RF mixers 108 to 115 formed of coupled transistor pairs (108 & 109, 110 & 111, 112 & 113, 114 & 115) whose outputs are connected (currents summed) with opposite phases. The transistors 108 to 115 are used as switches that are controllable by the in-phase and quadrature (I and Q) positive and negative (P and N) differential local oscillator voltages V_{LOIP}, V_{LOIN}, V_{LOQP} and V_{LOQN}. The local oscillator signals may be generated, e.g., by a local oscillator via a 0°/90° phase shifting element (not shown in FIG. 1). The current-mode passive IQ mixer 104 also comprises two decoupling capacitors 106, 107 connected (directly) between the SE2D transconductance amplifier 103 and the transistors 108 to 115 for ensuring that the switches are biased at zero DC (direct current) current.

The current-mode passive IQ mixer 104 is followed in the receiver chain by two transimpedance amplifiers (TIAs) 116, 117 which serve to perform current-to-voltage conversion with low-pass filtering for the I and Q baseband signals outputted by the current-mode passive IQ mixer 104, respectively, while presenting low input impedance to the current-mode passive IQ mixer 104 at the frequency of interest. Specifically, each of the transimpedance amplifiers 116, 117 comprises an operational amplifier 124, 129, a first feedback resistor 123, 128 and a first feedback capacitor 122, 127 arranged in parallel with an inverted input and a non-inverted output of the operational amplifier 124, 129, a second feedback resistor 125, 130 and a second feedback capacitor 126, 131 arranged in parallel with a non-inverted input and an inverted output of the operational amplifier 124, 129.

The two transimpedance amplifiers 116, 117 are followed in the receiver chain by two analog baseband filters 118, 119, respectively, which provide output differential I and Q baseband signals 120, 121. Said two analog baseband filters 118, 119 may be specifically low-pass filters.

It should still be emphasized that FIG. 1 corresponds to one simplified example of a radio receiver to which tunable radio frequency filters according to embodiments may be applied. In practical implementations of a radio receiver (or a radio transceiver) used in connection with embodiments, one or more further analog and/or digital elements (e.g., one or more antenna matching circuits, one or more RF and/or baseband filters, one or more amplifiers and/or one or more harmonic rejection downconversion mixers) may be provided.

FIG. 2 illustrates a circuit topology of a SE2D transconductance amplifier 200 according to embodiments. The illustrated SE2D transconductance amplifier 200 may correspond to SE2D G_{M} 103 of FIG. 1. Specifically, the SE2D transconductance amplifier 200 may be a SE2D transconductance CMOS amplifier.

The SE2D CMOS transconductance amplifier 200 is configured to convert the single-ended input voltage applied to the input terminal (IN) 231 to the differential output currents available at the positive and negative terminals (OUT+/OUT−) 232, 233 of the differential output of the SE2D CMOS transconductance amplifier 200 via amplification of equivalent transconductance. As a CMOS structure, the presented SE2D CMOS transconductance amplifier 200 employs both n-type metal-oxide-semiconductor (NMOS) transistors 201 to 204 as well as p-type metal-oxide-semiconductor (PMOS) transistors 205, 206. Notably, the SE2D CMOS transconductance amplifier 200 does not utilize any inductors, which results in small used silicon area and low cost. The CMOS architecture also leads to higher equivalent transconductance or voltage-to-current gain for a given current consumption compared to employing only NMOS transistors or only PMOS transistors.

In the following, the circuit topology of the SE2D CMOS transconductance amplifier 200 is discussed in more detail.

As mentioned above, the SE2D CMOS transconductance amplifier 200 comprises an input 231 (equally called an input terminal or an input port) for receiving a radio frequency signal. Said input 231 may provide a connection to an LNA (e.g., the LNA 102 of FIG. 1).

The SE2D CMOS transconductance amplifier 200 further comprises altogether following NMOS or PMOS transistors:
a first common-source (CS) NMOS transistor M₁ 201,
a second CS NMOS transistor M₂ 202,
a first cross-coupled cascode NMOS transistor M₃ 203,
a second cross-coupled cascode NMOS transistor M₄ 204,
a first CS PMOS transistor M₅ 205 and
a second CS PMOS transistor M₆ 206.

The first CS NMOS and CS PMOS transistors M₁ & M₅ 201, 205 serve to convert the RF input voltage to RF currents, which are ideally out-of-phase (i.e., in 180-degree offset) with the RF input voltage. Both the first CS NMOS and the first CS PMOS transistors M₁ & M₅ 201, 205 have a gate which is coupled via a first capacitor C₁ 211 and a fifth capacitor C₅ 215 to the input 231, respectively. The source of the first CS NMOS transistor M₁ 201 is connected (directly) to the ground. The drain of the first CS NMOS transistor M₁ 201 is connected (directly) to the source of the first cross-coupled cascode NMOS transistor M₃ 203 and coupled via a second capacitor C₂ 212 to the gate of the second NMOS transistor M₂ 202 and coupled via a sixth capacitor C₆ 216 to the gate of the second CS PMOS transistor M₆ 206. The source and the drain of the first CS PMOS transistor M₅ 205 is connected (directly) to the source of the second CS PMOS transistor M₆ 206 and to the drain of the first cross-coupled cascode CS NMOS transistor M₃ 203, respectively. The source of the first and second CS PMOS transistors M₅ & M₆ 205, 206 are connected (directly) to a positive (DC) supply voltage input (VDD).

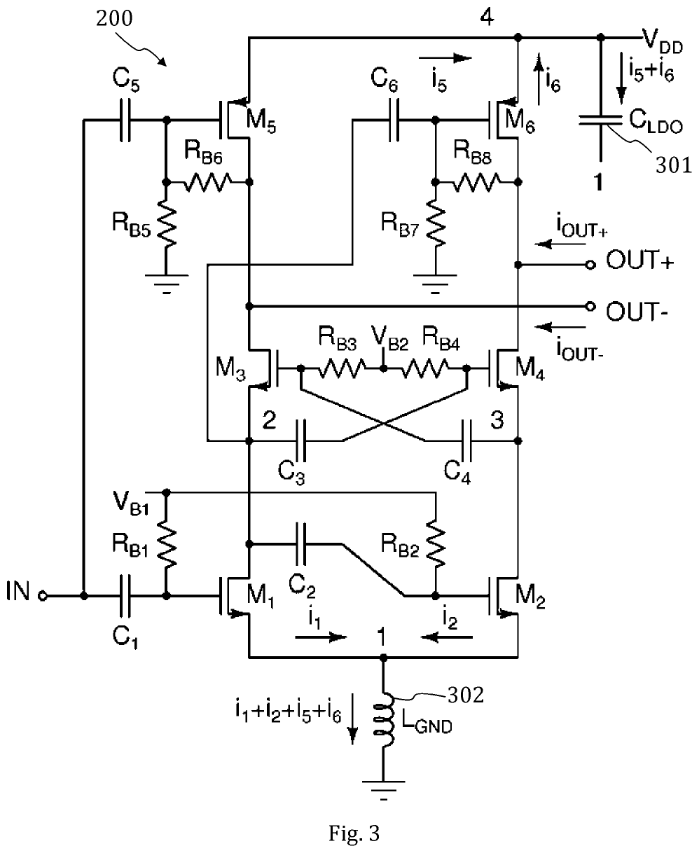

The second CS NMOS and CS PMOS transistors M₂ & M₆ 202, 206 are auxiliary transistors which serve to convert the voltage at the drain of the first CS NMOS transistor M₁ 201 (or equally at the source of the first cross-coupled cascode NMOS transistor M₃ 203) to RF currents which are ideally in-phase or in the same phase with the RF input voltage. It should be noted that said voltage at the source of the first cross-coupled cascode NMOS transistor M₃ 203 corresponds specifically (at least in the ideal case) to an inverted RF input voltage (i.e., the voltage received via the input 231 with an inverted sign), as will be described in more detail in connection with FIG. 3. Specifically, the gate of the second CS NMOS transistor M₂ 202 is coupled via the second capacitor C₂ 212 to the drain of the first CS NMOS transistor M₁ 201, the source of the second CS NMOS transistor M₂ 202 is connected (directly) to the ground and the drain of the second CS NMOS transistor M₂ 202 is connected (directly) to the source of the second cross-coupled cascode NMOS transistor M₄ 204 and coupled via a fourth capacitor C₄ 214 to the gate of the first cross-coupled cascode NMOS transistor M₃ 203. The gate of the second CS PMOS transistor M₆ 206 is coupled via a sixth capacitor C₆ 216 to both the drain of the first CS NMOS transistor M₁ 201 and the source of the first cross-coupled cascode NMOS transistor M₃ 203, the source of the second CS PMOS transistor M₆ 206 is connected (directly) to the source of the first CS PMOS transistor M₅ 205 and the drain of the second CS PMOS transistor M₆ 206 is connected (directly) to the drain of the second cross-coupled cascode NMOS transistor M₄ 204. The source of the second CS PMOS transistor M₆ 206 are connected (directly) to said positive (DC) supply voltage input (VDD).

The first and second CS NMOS transistors M₁ & M₂ 201, 202 have substantially equal transconductances. Specifically, the first and second CS NMOS transistors M₁ & M₂ 201, 202 may have substantially equal aspect ratios, i.e., width/length (W/L) ratios, leading to said substantially equal transconductances. Similarly, the first and second CS PMOS transistors M₅ & M₆ 205, 206 have substantially equal transconductances. Specifically, the first and second CS PMOS transistors M₅ & M₆ 205, 206 may have substantially equal aspect ratios leading said substantially equal transconductances.

The first and second cross-coupled cascode NMOS transistors M₃ & M₄ 203, 204 form a cross-coupled cascode stage for improving the balance of RF output currents of the first and second CS NMOS transistors M₁ & M₂ 201, 202. The gate of the first cross-coupled cascode NMOS transistor M₃ 203 is coupled via the fourth capacitor C₄ 214 to the source of the second cross-coupled cascode NMOS transistor M₄ 204 (a first cross-coupling connection) as well as to the drain of the second CS NMOS transistor M₂ 202. Moreover, the source of the first cross-coupled cascode NMOS transistor M₃ 203 is connected (directly) to the drain of the first CS NMOS transistor M₁ 201 and coupled via the sixth capacitor C₆ 216 to the gate of the second CS PMOS transistor M₆ 206 (a second cross-coupling connection). Finally, the drain of the first cross-coupled cascode NMOS transistor M₃ 203 is connected (directly) to the drain of the first CS PMOS transistor M₅ 205.

A gate of the second cross-coupled cascode NMOS transistor M₄ 204 is coupled via a third capacitor C₃ 213 to a source of the first cross-coupled cascode NMOS transistor M₃ 203 (the second cross-coupling connection), also via the third capacitor C₃ 213 to a drain of the first CS NMOS transistor M₁ 201 and via the third and sixth capacitors C₃ & C₆ 213, 216 to a gate of the second CS PMOS transistor M₆ 206. Moreover, the source of the second cross-coupled cascode NMOS transistor M₄ 204 is connected (directly) to a drain of the second CS NMOS transistor M₂ 202 as well as coupled via the fourth capacitor C₄ 214 to the gate of the first cross-coupled cascode NMOS transistor M₃ 203 (the first cross-coupling connection). Finally, a drain of the second cross-coupled cascode NMOS transistor M₄ 204 is connected (directly) to a drain of the second CS PMOS transistor M₆ 206.

Here, the first and second cross-coupled cascode NMOS transistors M₃ & M₄ 203, 204 may have substantially equal transconductances. Specifically, the first and second cross-coupled cascode NMOS transistors M₃ & M₄ 203, 204 may have substantially equal aspect ratios leading to said substantially equal transconductances.

Positive and negative terminals 232, 233 of the differential output of the SE2D CMOS transconductance amplifier 200 are provided between the drain of the second CS PMOS transistor M₆ 206 and the drain of the second cross-coupled cascode NMOS transistor M₄ 204 and between the drain of the first CS PMOS transistor M₅ 205 and the drain of the first cross-coupled cascode NMOS transistor M₃ 203, respectively.

The SE2D CMOS transconductance amplifier 200 may further comprise various biasing means for (DC) biasing the CS NMOS and CS PMOS transistors M₁ to M₆ 201 to 206. Said biasing means may comprise means for inputting (and optionally generating) one or more biasing DC voltages (in the illustrated example, specifically three biasing voltages V_{DD}, V_{B1} and V_{B2}) for biasing the transistors M₁ to M₆ 201 to 206. As shown in FIG. 2, the first and second CS NMOS transistors M₁ & M₂ 201, 202 may be biased using a first secondary biasing voltage input V_{B1} 242 and the first and second cross-coupled cascode NMOS transistors M₃ & M₄ 203, 204 may be biased using a second secondary biasing voltage input V_{B2} 243, for example. In general, one or more biasing voltage inputs 241 to 243 may be provided for biasing the transistors M₁ to M₆ 201 to 206 in a desired manner.

Additionally or alternatively, the biasing means may comprise one or more (DC-blocking) capacitors for blocking the (DC) biasing currents (i.e., for preventing the flow of the DC biasing currents to circuit elements other than the transistor(s) to be biased). Said one or more DC-blocking capacitors may specifically comprise the aforementioned first, second, third, fourth, fifth and/or sixth capacitors C₁-C₆ 211 to 216. Depending on how the biasing means are implemented, a different number of DC-blocking capacitors may be used.

In some embodiments, one or more of the first, second, fifth and sixth capacitors C₁, C₂, C₅ & C₆ 211, 212, 215, 216 may be omitted (i.e., the associated AC-coupled connection(s) may be replaced with DC-coupled connection(s)).

One or more of the definitions listed above may hold especially for embodiments employing a different biasing scheme compared to the one shown in FIG. 2.

Additionally or alternatively, the biasing means may comprise one or more biasing resistors for adjusting the biasing and/or one or more isolating resistors for isolating the one or more biasing voltage inputs 241 to 243 from the radio frequency signal paths. The one or more biasing resistors may specifically serve to adjust DC biasing voltages applied to one or more terminals of the transistors M₁ to M₆ 201 to 206. In the illustrated example, four biasing resistors R_{B5} to R_{B8} 225 to 228 and four isolating resistors R_{B1} to R_{B4} 221 to 224 are provided. Specifically, said one or more biasing resistors (or specifically here said four biasing resistors R_{B5} to R_{B8} 225 to 228) may be used for realizing a voltage division-based biasing circuits. Said voltage division-based biasing circuits serve to tune the DC voltages at the gates of the first and second CS PMOS transistors 205, 206 M₅ & M₆.

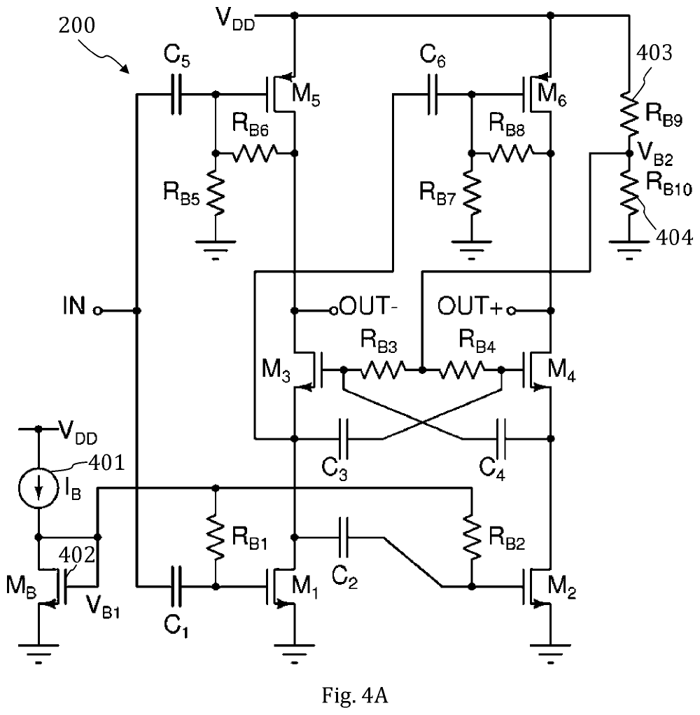

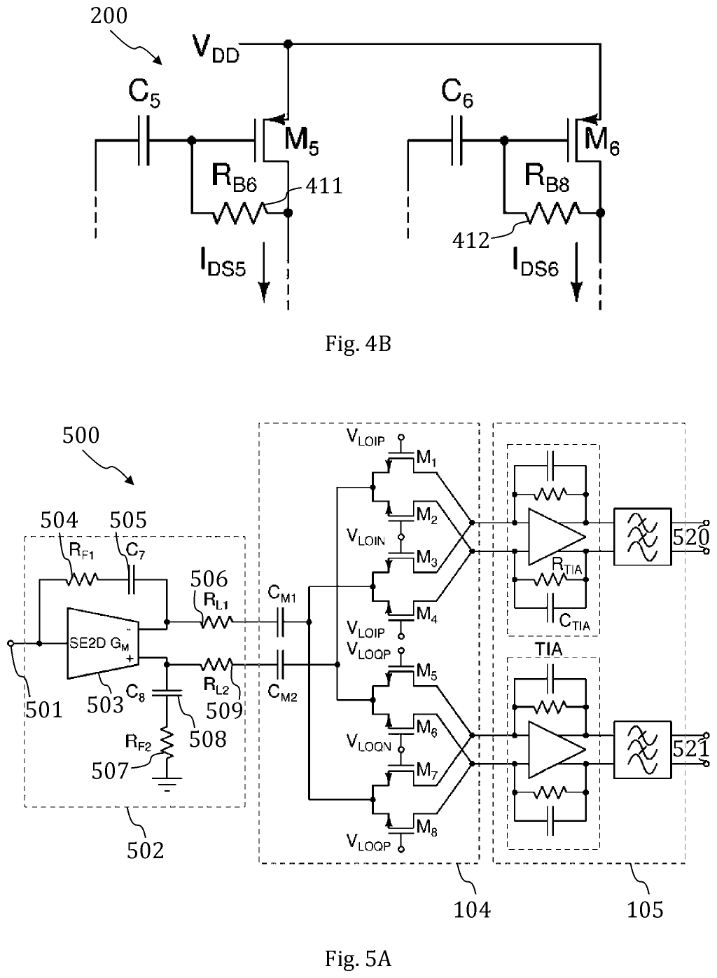

In some embodiments, said biasing means may comprise means for generating the DC biasing voltage V_{B2} from V_{DD} (e.g., using voltage division with biasing resistors). Such means for generating specifically V_{B2} are described in detail below in connection with FIG. 4A.

Biasing schemes are discussed in more detail in connection with FIGS. 4A and 4B.

It should be emphasized that biasing of the transistors M₁ to M₆ 201 to 206 may be implemented in a variety of different ways and thus the biasing solution presented in FIG. 2 should be considered merely as an example of a possible biasing scheme.

In the following, the operation of the SE2D CMOS transconductance amplifier 200 of FIG. 2 is discussed in more detail specifically in reference to FIG. 3 which shows the SE2D CMOS transconductance amplifier 200 with some additional notation for facilitating the discussion. Most of the reference signs included in FIG. 2 have been omitted in FIG. 3 merely for clarity of presentation.

In FIG. 3, it is assumed that a low-dropout (LDO) regulator is used for generating the supply voltage V_{DD} for the SE2D CMOS transconductance amplifier 200 which is a conventional technique in analog and RF integrated circuits. At the LDO output, large capacitor 301 of C_{LDO} connects V_{DD} terminal (or node 4) to on-chip amplifier ground (or node 1).

In the following, the transistors are modelled as linear voltage-controlled current sources and capacitive effects are neglected for simplicity. The circuit is excited with an input voltage v_{IN} applied to the input terminal IN. Inductance L_{GND} 302 models parasitic ground inductance. Ideally, L_{GND} should have small effect on circuit performance.

From FIG. 3, the drain-source (AC) currents of M₁ and M₂ are given as

$$\begin{matrix}{i}_{1} = {g}_{m 1} ( {v}_{IN} - {v}_{1} ) & ( 1 ) \\ {i}_{2} = {g}_{m 1} ( {v}_{2} - {v}_{1} ) , & ( 2 )\end{matrix}$$

where v_{IN}, v₁, and v₂ are the voltages at the circuit nodes IN, 1 and 2, respectively. The currents i₁ and i₂ can also be written as

$$\begin{matrix}{i}_{1} = {g}_{m 3} ( {v}_{3} - {v}_{2} ) & ( 3 ) \\ {i}_{2} = {g}_{m 3} ( {v}_{2} - {v}_{3} ) . & ( 4 )\end{matrix}$$

Summing both sides of (3) and (4) results in

$${i}_{1} + {i}_{2} = {g}_{m 3} ( {v}_{3} - {v}_{2} + {v}_{2} - {v}_{3} ) = 0. \qquad ( 5 )$$

Also, summing both sides of (1) and (2) results in

$${i}_{1} + {i}_{2} = {g}_{m 1} ( {v}_{IN} + {v}_{2} - 2 {v}_{1} ) = 0 , \qquad ( 6 )$$

where equivalence from (5) is used. From (6), we get

$${v}_{IN} + {v}_{2} - 2 {v}_{1} = 0. \qquad ( 7 )$$

In addition, according to FIG. 3, the drain-source (AC) currents generated by M₅ and M₆ are given as (taking into account that v₄=v₁ due to the LDO output capacitor C_{LDO})

$$\begin{matrix}{i}_{5} = {g}_{m 5} ( {v}_{IN} - {v}_{1} ) & ( 8 ) \\ {i}_{6} = {g}_{m 5} ( {v}_{2} - {v}_{1} ) . & ( 9 )\end{matrix}$$

Adding both sides of (8) and (9) together, we get

$${i}_{5} + {i}_{6} = {g}_{m 5} ( {v}_{IN} + {v}_{2} - 2 {v}_{1} ) = 0 , \qquad ( 10 )$$

where the equation (7) has been taken into account. Combining the results from (5) and (10), we get

$${i}_{1} + {i}_{2} + {i}_{5} + {i}_{6} = 0. \qquad ( 11 )$$

In other words, no AC-currents flow thorough the parasitic ground inductance L_{GND} and therefore v₁=0. Thus, as a first order approximation, L_{GND} has no effect on circuit performance, as desired.

$$With {v}_{1} = 0 , we have \\ {v}_{2} = - {v}_{IN} \qquad ( 12 )$$

which follows from (7). That is, as a first-order approximation, the voltage at the source of M₃ (node 2) corresponds to an inverted copy of the input voltage v_{IN}.

Finally, from FIG. 3, the negative and positive output RF currents can be written as (with v₁=0 and v₂=−v_{IN})

$$\begin{matrix}{i}_{OUT -} = {i}_{1} + {i}_{5} = ( {g}_{m 1} + {g}_{m 5} ) {v}_{IN} & ( 13 ) \\ {i}_{OUT +} = {i}_{2} + {i}_{6} = - ( {g}_{m 1} + {g}_{m 5} ) {v}_{IN} & ( 14 )\end{matrix}$$

These currents represent the equivalent output currents driven to the short-circuited load. It is seen that the positive and negative output currents of the proposed CMOS transconductance amplifier 200 have equal magnitude and 180° phase shift relative to each other. It is concluded that the proposed CMOS transconductance amplifier 200 shown in FIG. 3 converts the single-ended input voltage to the differential output current, that is, it performs single-ended-to-differential conversion as desired.

The voltage-to-current gain or equivalent transconductance of the proposed circuit can be written as

$${G}_{m} = \vert \frac{{i}_{OUT +} - {i}_{OUT -}}{{v}_{IN}} \vert = 2 ( {g}_{m 1} + {g}_{m 5} ) . \qquad ( 15 )$$

In other words, voltage-to-current gain is twice the sum of transconductances of the first common-source N- and PMOS transistors M₁ and M₅. The factor of 2 comes from the single-ended-to-differential conversion.

As mentioned above, various biasing means may be provided for biasing the CS NMOS and CS PMOS transistors. FIGS. 4A and 4B illustrate exemplary biasing schemes for the SE2D CMOS transconductance amplifier according to embodiments. Specifically, FIG. 4A show a biasing scheme for the whole SE2D CMOS transconductance amplifier while FIG. 4B shows an alternative biasing scheme specifically for the first and second CS PMOS transistors M₅ and M₆ (with the biasing of other transistors being carried out as shown in FIG. 4A also in this case). The SE2D CMOS transconductance amplifier 200 shown in FIGS. 4A and 4B (or at least shown in part) may correspond fully to the SE2D CMOS transconductance amplifier 200 discussed in connection with FIGS. 2 and 3. The reference signs included in FIG. 2 have been omitted here merely for simplicity of presentation.

Referring to FIG. 4A, the biasing of the first and second CS NMOS transistors M₁ & M₂ is provided using a simple bias current mirror formed by a diode-connected transistor MB 402 and the first and second CS NMOS transistors M₁ & M₂ to copy (or mirror) the bias current I_{B} 401. It should be noted that copying or mirroring the bias current I_{B} 401 does not necessarily imply here that the original and copied/mirrored currents are equal. Neglecting the channel-length modulation, the drain-source current of the first (or second) CS NMOS transistor M₁ (M₂) may be written simply as I_{DS1}=(W/L)₁/(W/L)_{B}I_{B}, where (W/L)_{B} is the aspect ratio of M_{B}. In fact, in the proposed amplifiers, I_{DS1}=I_{DS2}=I_{DS3}=I_{DS4}. If a simple current mirror formed by M_{B} and M₁-M₂ does not suffice, it is also possible to employ more elegant current mirror techniques.

In FIG. 4A, the bias voltage (V_{B2}) at the gate of the cascode of the first and second cross-coupled cascode NMOS transistors M₃ & M₄ is generated via resistive division by R_{B9} and R_{B10} from supply voltage V_{DD}. The bias voltage V_{B2} may, thus, be written simply as

$${V}_{B 2} = \frac{{R}_{{B}_{10}}}{{R}_{{B}_{9}} + {R}_{{B}_{10}}} {V}_{DD} .$$

Biasing of the first and second CS PMOS transistors M₅ and M₆ may be implemented in at least two different ways. In some simplistic embodiments, the bias resistors R_{B5} and R_{B7} shown in FIG. 4A may be omitted altogether and thus only the resistors R_{B6} and RBs may be used for the biasing of M₅ and M₆. This alternative biasing scheme is shown in FIG. 4B. In the arrangement illustrated in FIG. 4B, the drain and gate of M₅ (M₆) are tied together at DC and M₅ (M₆) forms a diode-connected transistor at DC. In other words, the drain and gate DC voltages of M₅ (M₆) are equal in FIG. 4B, that is, we have V_{D5}=V_{G5}. However, the solution presented in FIG. 4B has the disadvantage that, at low supply voltages, a considerable amount of voltage headroom is wasted. It would be sufficient to bias the drain of M₅ (M₆) at maximum by amount of |V_{tP}| higher than the gate of M₅ (M₆) or V_{D5}≤(V_{G5}+|V_{tP}|) in order to guarantee that M₅ (M₆) remains in saturation. Here, V_{tP} is the threshold voltage of the first and second CS PMOS transistors M₅ and M₆.

To overcome this disadvantage, an additional resistor R_{B5} (R_{B7}) may be introduced between the gate of M₅ (M₆) and the ground as shown in FIG. 4A. With the introduction of said additional resistor, the DC level of M₅ (M₆) drain can be shifted upwards. Namely, from FIG. 4A, it is easy to show that the following holds:

$${V}_{D 5} = {V}_{G 5} + \frac{{R}_{{B}_{6}}}{{R}_{{B}_{5}}} {V}_{G 5} \qquad ( 16 )$$

Thus, the drain of M₅ (M₆) is biased to a voltage (V_{D5}), which is higher than the voltage V_{G5} at the gate of M₅ (M₆) by the amount of

$$\frac{{R}_{{B}_{6}}}{{R}_{{B}_{5}}} {V}_{G 5} .$$

In other words, the resistance ratio of R_{B6}/R_{B5} can be chosen to set the drain voltage of M₅ (M₆) to a desired value. From (16) it is also seen that the drain voltage of M₅ (M₆) tracks the gate voltage of M₅ (M₆), which is desired so as to compensate process and temperature variations. As the biasing scheme consisting of resistors R_{B5} and R_{B6} (R_{B7} and R_{B8}) enables operation at low supply voltage, it may be preferred over the simpler biasing scheme shown in FIG. 4B.

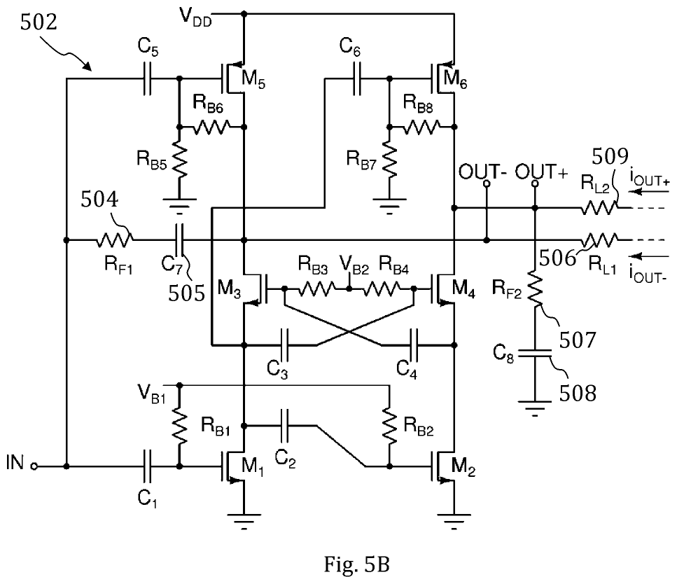

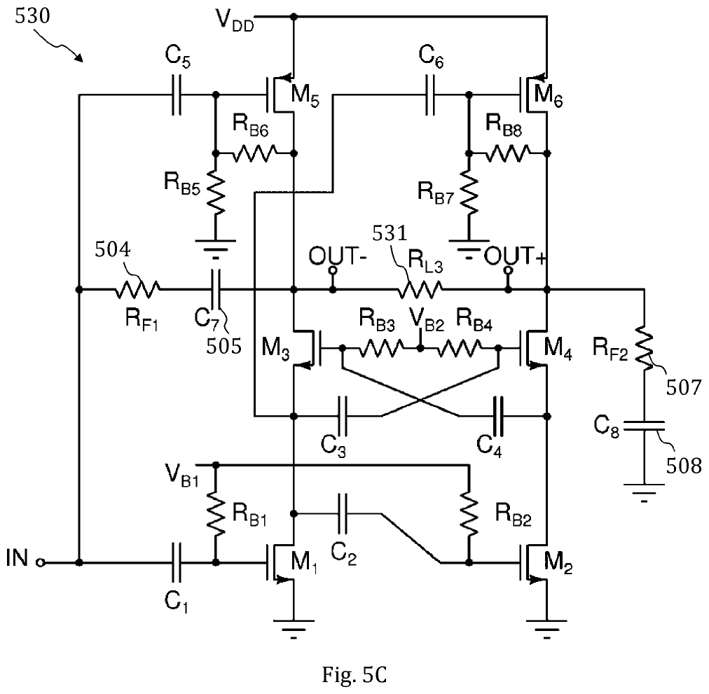

Instead of realizing the single-ended-to-differential conversion in a separate SE2D transconductance amplifier, the single-ended-to-differential conversion may be alternatively realized in an LNA of a receiver chain. Such a SE2D LNA may be realized by combining the SE2D CMOS transconductance amplifier according to embodiments as discussed above with a resistive (negative) feedback (RFB) around said SE2D CMOS transconductance amplifier so as to set the LNA input impedance to a certain desired value (usually matching a characteristic impedance of the antenna or preselection RF filter connecting to the LNA having typically the value of 50Ω). FIG. 5A illustrates a direct-conversion radio receiver architecture 500 with such a single-ended-to-differential resistive-feedback CMOS LNA 502 driving a current-mode passive IQ mixer 104 while FIG. 5B illustrates the single-ended-to-differential resistive-feedback CMOS LNA 502 in more detail. FIG. 5C illustrates a minor variation 530 of the single-ended-to-differential resistive-feedback CMOS LNA 502 of FIG. 5B. In FIGS. 5A and 5B, it is assumed that the down conversion mixer is realized as a passive current-mode architecture. In FIGS. 5A, 5B and 5C, most reference signs for elements previously already included in FIGS. 1 and 2 have been omitted merely for simplicity of presentation.

Referring to FIG. 5A, the direct conversion radio receiver 500 comprises a SE2D CMOS RFB LNA 502, a current-mode passive IQ mixer 104 and an analog baseband (ABB) circuitry 105 (listed in the order of signal reception in the RF chain of the radio receiver 500). The elements 104, 105 may correspond fully to the corresponding elements of FIG. 1. The port or terminal 501 corresponds to an RF input port or terminal while the two differential pairs of ports or terminals 520, 521 correspond to baseband differential in-phase (I) and quadrature (Q) signal outputs. The elements 501, 520, 521 may be defined as discussed for elements 101, 120, 121 of FIG. 1 above.

Referring to FIGS. 5A and 5B, the SE2D CMOS resistive-feedback LNA 502 comprises a SE2D CMOS transconductance amplifier 503 which is configured to receive a RF input signal via the input terminal 501. The SE2D CMOS transconductance amplifier 503 may fully correspond to the SE2D CMOS transconductance amplifier 200 of FIG. 2, as can been also from FIG. 5B. The SE2D CMOS resistive-feedback LNA 502 further comprises a feedback resistor R_{F1} 504 connected (directly) between the negative terminal (OUT−) of the differential output and the input (IN) of the SE2D CMOS transconductance amplifier 503. The SE2D CMOS resistive-feedback LNA 502 further comprises first and second load resistors R_{L1} & R_{L2} 506, 509 connected (directly) to the negative and positive terminals of the differential output of the SE2D CMOS transconductance amplifier 503, respectively. Negative and positive terminals of the differential output of the SE2D CMOS resistive-feedback LNA 502 are provided via said first and second load resistors R_{L1} & R_{L2} 506, 509. In other words, said first and second load resistors R_{L1} & R_{L2} 506, 509 are connected (directly) between the negative and positive terminals of the differential output of the SE2D CMOS transconductance amplifier 503 and the negative and positive terminals of the differential input of the current-mode passive IQ mixer 104.

For DC blocking purposes, the SE2D CMOS resistive-feedback LNA 502 may also comprise a feedback capacitor C₇ 505 connected in series with the feedback resistor R_{F1} 504 so as to form a first series circuit. Specifically, the first series circuit may be connected (directly) between the negative terminal (OUT−) of the differential output and the input (IN) of the SE2D CMOS transconductance amplifier 503.

Additionally or alternatively, the SE2D CMOS resistive-feedback LNA 502 may comprise a resistor R_{F2} 507 connected in series with the capacitor C₈ 508 so as to form a second series circuit which is connected between the positive terminal (OUT+) of the differential output of the SE2D CMOS transconductance amplifier 503 and the ground.

The proposed SE2D CMOS RFB LNA 502 converts the single-ended input voltage VIN applied to the input terminal (IN) 501 to the differential output voltage available at the LNA output v_{OUT}=(v_{OUT+}−v_{OUT-}) with amplification. Also, the differential output current is available at the LNA output via the first and second load resistors R_{L1} and R_{L2} 506, 509. The first and second load resistors 506, 509 may have specifically equal resistances (R_{L2}=R_{L1}=R_{L}).

As discussed with the SE2D CMOS transconductance amplifier according to embodiments in connection with FIGS. 1 to 3, in the SE2D RFB LNA 502 shown in FIGS. 5A and 5B, the first N- and PMOS transistors M₁ and M₅, respectively, convert the RF input voltage to RF currents, which are ideally out-of-phase (i.e., in 180-degree offset) with the RF input voltage. Transistors M₂ and M₆ are auxiliary common-source transistors which convert the inverted RF input voltage to RF currents, which are ideally in-phase or in same phase with the RF input voltage. Transistors M₃ and M₄ form a cross-coupled cascode stage, which improves the balance of RF output currents of M₁ and M₂. The values of the bias resistors R_{B1}-R_{B8} may be selected to be large (e.g., at least 10 kΩ). Additionally or alternatively, the values of the DC-blocking capacitors C₁-C₈ may be selected to be large (e.g., at least 1 pF or 2 pF) so that they resemble short-circuits at the (radio) frequency of interest. The required bias voltages V_{B1} and V_{B2} can be generated with many well-known techniques, as described also above.

In the presented SE2D RFB CMOS LNA 502, the first and second CS NMOS transistors M₁ & M₂ have equal aspect ratio (W/L) and thus their transconductances may also be equal, i.e., gₘ₁=gₘ₂. Similarly, the aspect ratios of the first and second cross-coupled cascode NMOS transistors M₃ & M₄ may be equal and their transconductances may also be equal or gₘ₃=gₘ₄. Also, the first and second CS PMOS transistors M₅ & M₆ may have equal aspect ratio (W/L) and therefore gₘ₅=gₘ₆ may hold.

Resistive feedback with feedback resistance R_{F1} 504 is employed to create the real part of the LNA input impedance. The resistor R_{F2} 507 (R_{F2}=R_{F1}=R_{F}) may be used for balancing the output voltages and currents. However, in practice, R_{F2} 507 may not be needed and thus it may be considered optional. In the same way as in the proposed SE2D transconductor, in the presented SE2D RFB LNA, in the first order approximation no AC-currents flow thorough the parasitic ground inductance L_{GND} (not shown in FIG. 5A or 5B). Thus, the performance of the proposed SE2D RFB CMOS LNA is not sensitive to the parasitic supply impedances as desired.

The SE2D RFB CMOS RFB LNA 502 implements the LNA input matching via negative voltage-current feedback. At low or moderate frequencies, the input resistance of the LNA 502 (R_{IN}) shown in FIG. 5B is given as

$${R}_{IN} = {R}_{S} = \frac{{R}_{F} + {R}_{L}}{( {g}_{m 1} + {g}_{m 5} ) {R}_{L}} \qquad ( 17 )$$

Here, the equality R_{IN}=R_{S} means that the LNA input resistance needs to be designed to match the source resistance (R_{S}, usually 50Ω).

At impedance match (R_{IN}=R_{S}), the LNA voltage gain can be expressed as

$${A}_{V , LNA} = \vert \frac{{v}_{OUT}}{{v}_{IN}} \vert = \vert \frac{{v}_{OUT +} - {v}_{OUT -}}{{v}_{IN}} \vert = \frac{2 {R}_{F}}{{R}_{S}} \qquad ( 18 )$$

Similarly, at impedance match, the differential LNA RF output current towards the current-mode passive IQ mixer 104 is

$${i}_{OUT} = {i}_{OUT +} - {i}_{OUT -} = \frac{{v}_{OUT}}{{R}_{L}} = \frac{2 {R}_{F}}{{R}_{S} {R}_{L}} {v}_{IN} \qquad ( 19 )$$

based on which the LNA equivalent transconductance is given as

$${G}_{m , LNA} = \frac{{i}_{OUT}}{{v}_{IN}} = \frac{2 {R}_{F}}{{R}_{S} {R}_{L}} \qquad ( 20 )$$

Thus, besides being a voltage amplifier, the proposed SE2D CMOS RFB LNA 502 can be modelled as a transconductance amplifier, which converts the incoming single-ended RF voltage to the differential RF output current, which is driven to the current-mode passive IQ mixer 104. The current-mode passive IQ mixer 104 downconverts the RF current to the baseband (BB) current, which is driven to the I and Q transimpedance amplifiers. The TIAs convert the BB current to BB voltage with low-pass filtering.

The noise figure (NF) of the presented SE2D CMOS RFB LNA can be approximated as

$$NF = 1 + \frac{γ}{{g}_{m 1} {R}_{S}} + \frac{γ {g}_{m 5}^{2}}{{{g}_{m 1} ( {g}_{m 1} + {g}_{m 5} )}^{2} {R}_{S}} + \frac{2 γ {g}_{m 3}}{{g}_{m 1}^{2} {R}_{S}} + \frac{γ {g}_{m 5}}{{( {g}_{m 1} + {g}_{m 5} )}^{2} {R}_{S}} + \frac{{R}_{S}}{{R}_{F}} \qquad ( 21 )$$

The first term after ‘1’ is due to the first CS NMOS transistor M₁, the second term is due to the second (auxiliary) CS NMOS transistor M₂, the third term is due the cross-coupled cascode of first and second cross-coupled cascode NMOS transistors M₃ & M₄, the fourth term is due to the second (auxiliary) CS PMOS transistor M₆, and the last term is due to the feedback resistor R_{F1} 504. Here, it is assumed that the excess noise coefficients of N- and PMOS transistors are equal, i.e., γ_{N}=γ_{P}=γ.

Interestingly, the noise due to the first CS PMOS transistor M₅ does not appear in equation (21). In fact, it can be shown that the noise due to M₅ appears as common-mode noise voltage at the differential LNA output and is therefore cancelled. In other words, the transistor M₅ contributes to the voltage-to-current amplification of the input signal but it does not contribute to the amplifier (differential) output noise. This is a clear benefit of the proposed SE2D RFB CMOS LNA 502.

The SE2D CMOS RFB LNA 502 provides multiple benefits. Both N- and PMOS transistors are utilized in the proposed LNA 502 which results in larger equivalent transconductance compared to using N- or PMOS transistors only. In addition, in the presented SE2D CMOS resistive-feedback LNA 502, load resistors 506, 509 consume no voltage headroom, which makes the circuit architecture well suited for low supply voltages. Finally, no on-chip inductors are employed in the SE2D CMOS resistive-feedback LNA 502, which results in low silicon area and cost.

In some cases, the SE2D CMOS RFB LNA 502 may need to drive a high-impedance capacitive load, instead of a low input impedance load presented by the current-mode passive IQ mixer 104. In such cases, a third load resistor R_{L3} (equally called a differential load resistor) may be connected (directly) between the negative and positive terminals of the differential output of the SE2D CMOS RFB LNA. The first and second load resistors R_{L2} & R_{L1}, as discussed in connection with FIGS. 5A and 5B, may be omitted in such cases. FIG. 5C illustrates a SE2D CMOS RFB LNA 530 with such a modification (i.e., inclusion of the third load resistor R_{L3} 531). Apart from the inclusion of the third load resistor R_{L3} 531 (and possible omission of the first and second load resistors R_{L2} & R_{L1}), the SE2D CMOS RFB LNA 530 of FIG. 5C may correspond to the SE2D CMOS RFB LNA 502 of FIGS. 5A and 5B.

In some embodiments, the SE2D CMOS RFB LNA 502 of FIG. 5B or the SE2D CMOS RFB LNA 530 of FIG. 5C may employ at least one off-chip impedance matching network or circuit.

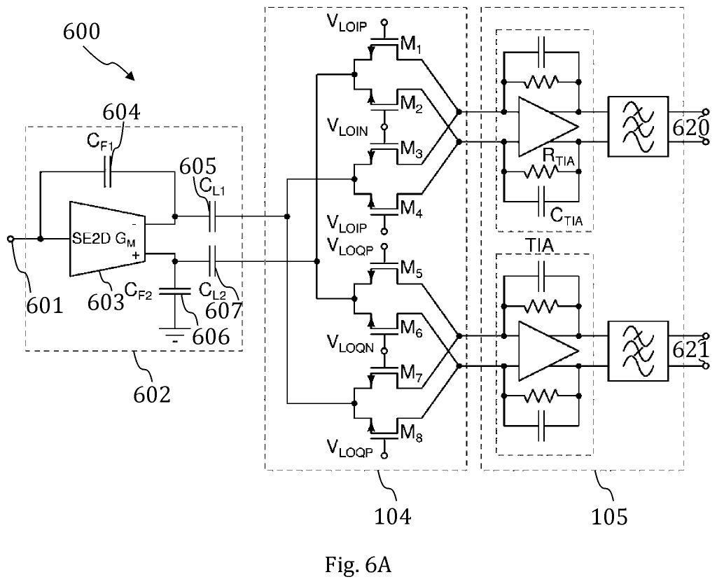

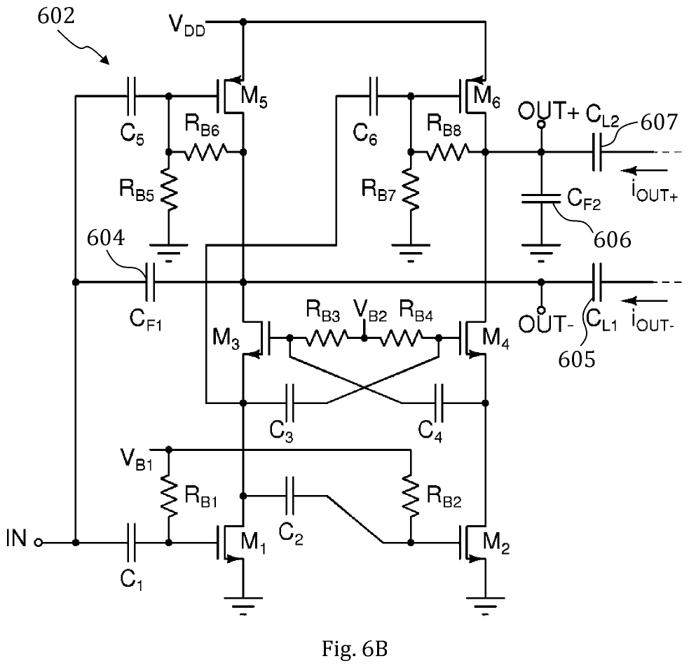

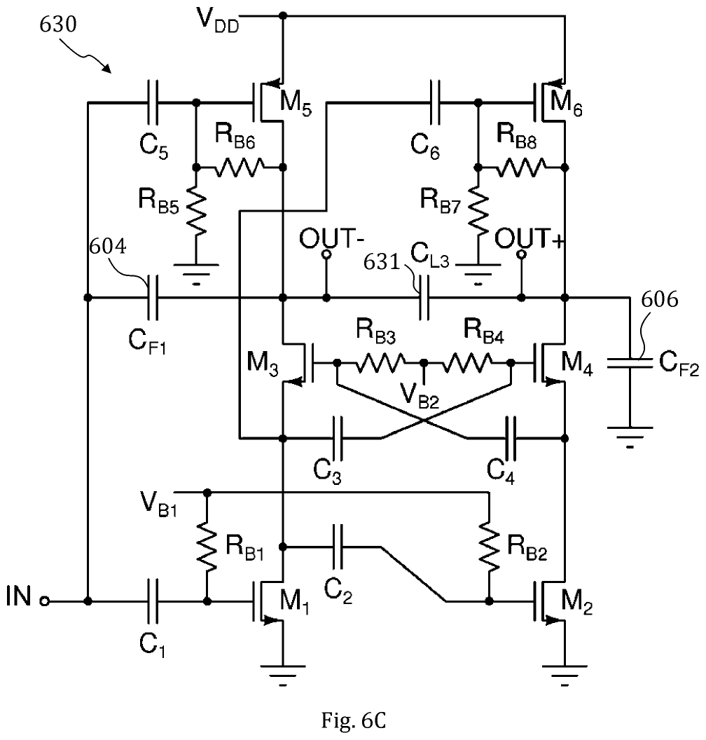

Instead of using resistive feedback, the SE2D LNA may be implemented using capacitive feedback. Such an alternative SE2D LNA may be realized by combining the SE2D CMOS transconductance amplifier according to embodiments as discussed above with a capacitive (negative) feedback (CFB) around said SE2D CMOS transconductance amplifier so as to set the LNA input impedance to a certain desired value (usually 50Ω). FIG. 6A illustrates a direct-conversion radio receiver architecture 600 with such a single-ended-to-differential capacitive-feedback CMOS LNA 602 driving a current-mode passive IQ mixer 104 while FIG. 6B illustrates the single-ended-to-differential capacitive-feedback CMOS LNA 602 in more detail. FIG. 6C illustrates a minor variation 630 of the single-ended-to-differential capacitive-feedback CMOS LNA 602 of FIG. 6B. Here, it is assumed that the down conversion mixer is realized as a passive current-mode architecture. In FIGS. 6A, 6B and 6C, most reference signs for elements previously included in FIGS. 1 and 2 have been omitted merely for simplicity of presentation.

Referring to FIG. 6A, the direct conversion radio receiver 600 comprises a SE2D CMOS CFB LNA 602, a current-mode passive IQ mixer 104 and an analog baseband (ABB) circuitry 105 (listed in the order of signal reception in the RF chain of the radio receiver 600). The elements 104, 105 may correspond fully to the corresponding elements of FIG. 1. The port or terminal 601 corresponds to an RF input port or terminal while the two differential pairs of ports or terminals 620, 621 correspond to baseband differential in-phase (I) and quadrature (Q) signal outputs, similar to corresponding ports of FIG. 1. The elements 601, 620, 621 may be defined as discussed for elements 101, 120, 121 of FIG. 1 above.

Referring to FIGS. 6A and 6B, the SE2D CMOS capacitive-feedback LNA 602 comprises a SE2D CMOS transconductance amplifier 603 which is configured to receive a RF input signal via the input terminal 601. The SE2D CMOS transconductance amplifier 603 may fully correspond to the SE2D CMOS transconductance amplifier 200 of FIG. 2, as can been also from FIG. 6B. The SE2D CMOS capacitive-feedback LNA 602 further comprises a feedback capacitor C_{F1} 604 connected (directly) between the negative terminal (OUT−) of the differential output and the input (IN) of the SE2D CMOS transconductance amplifier 603. The SE2D CMOS capacitive-feedback LNA 602 further comprises first and second load capacitors C_{L1} & C_{L2} 605, 607 connected (directly) to the negative and positive terminals of the differential output of the SE2D CMOS transconductance amplifier 603, respectively. Negative and positive terminals of the differential output of the SE2D CMOS capacitive-feedback LNA 602 are provided via said first and second load capacitors C_{L1} & C_{L2} 605, 607. In other words, said first and second load capacitors C_{L1} & C_{L2} 605, 607 are connected (directly) between the negative and positive terminals of the differential output of the SE2D CMOS transconductance amplifier 603 and the negative and positive differential inputs of the current-mode passive IQ mixer 104. It should be noted that no additional DC-blocking capacitors are needed in the LNA 602 or in the mixer 104.

Finally, the SE2D CMOS capacitive-feedback LNA 602 may also comprise a balancing capacitor C_{F2} 606 (for further balancing the output signals) connected (directly) between the positive terminal (OUT+) of the differential output of the SE2D CMOS transconductance amplifier 603 and the ground.

The SE2D CMOS CFB LNA 602 of FIG. 6B converts the single-ended input voltage VIN applied to the input terminal (IN) to the differential output voltage available at the LNA output v_{OUT}=(v_{OUT+}−v_{OUT-}) with amplification, similar to the SE2D CMOS CFB LNA 502 of FIG. 5A. Also, the differential output current is available at the LNA output via first and second load capacitors C_{L1} 605 and C_{L2} 607. The capacitances of the first and second load capacitors C_{L1} 605 and C_{L2} 607 may be equal (C_{L2}=C_{L1}=C_{L}).

Similar to the SE2D CMOS transconductance amplifier 200 of FIG. 2 and the SE2D RFB LNA 502 of FIG. 5B, in the SE2D CFB LNA 602 shown in FIG. 6B, the first common-source N- and PMOS transistors M₁ and M₅, respectively, convert the RF input voltage to the RF currents, which are ideally out-of-phase (i.e., in 180-degree offset) with the RF input voltage. The second common-source N- and PMOS transistors M₂ and M₆ are auxiliary common-source transistors, which convert the inverted RF input voltage to the RF currents, which are ideally in-phase or in same phase with the RF input voltage. The third and fourth common-source NMOS transistors M₃ and M₄ form a cross-coupled cascode stage, which improves the balance of RF output currents of M₁ and M₂. The values of the bias resistors R_{B1}-R_{B8} are selected to be large in FIG. 6B while the values of the DC-blocking capacitors C₁-C₆ are also selected to be large so that they resemble short-circuits at frequency of interest. The required bias voltages V_{B1} and V_{B2} can be generated with many well-known techniques, as described above.

In the SE2D CFB CMOS LNA 602, the first and second CS NMOS transistors M₁ & M₂ may have equal aspect ratios (W/L) and thus their transconductances may also be equal, i.e., gₘ₁=gₘ₂. Similarly, aspect ratios of the first and second cross-coupled cascode NMOS transistors M₃ & M₄ may be equal and their transconductances may also be equal (i.e., gₘ₃=gₘ₄). Also, the first and second CS PMOS transistors M₅ & M₆ may have equal aspect ratios (W/L) and therefore gₘ₅=gₘ₆ may hold. Capacitive feedback with feedback capacitance C_{F1} 604 is employed to create real part for the LNA input impedance.

A balancing capacitor C_{F2} 606 is connected between the positive terminal of the differential output of the SE2D CMOS transconductance amplifier 603 and the ground. The balancing capacitor C_{F2} 606 (which may be equal to C_{F1} 604, i.e., C_{F2}=C_{F1}=C_{F}) serves to balance the output voltages and currents. However, in practice, the balancing capacitor C_{F2} 606 may not be needed and thus it may be considered optional.

In the same way as discussed in connection with FIG. 3 for the SE2D CMOS transconductance amplifier 200 according to embodiments, in the SE2D CFB LNA 602 according to embodiments, no AC-currents flow thorough the parasitic ground inductance L_{GND} (not shown in FIG. 6A or 6B) in the first order approximation. Thus, the performance of the SE2D CFB CMOS LNA is not sensitive to the parasitic supply impedances.

It is easy to show that the input impedance of the SE2D CFB LNA 602 of FIGS. 6A and 6B is formed by the resistor R_{IN} in parallel with the capacitor C_{IN} defined as:

$${R}_{IN} = \frac{{C}_{F} + {C}_{L}}{{C}_{F}} \frac{1}{( {g}_{m 1} + {g}_{m 5} )} \& {C}_{IN} = \frac{{C}_{F} {C}_{L}}{{C}_{F} + {C}_{L}} . \qquad ( 22 )$$

Here, R_{IN} is the LNA input resistance and C_{IN} is the (undesired) LNA input capacitance. Assuming for now that at the frequency of interest (f₀), we have ω₀<<gₘ₁+gₘ₅/C_{L}, the LNA input resistance matching requirement may be written as

$${R}_{IN} = {R}_{S} = \frac{{C}_{F} + {C}_{L}}{{C}_{F}} \frac{1}{( {g}_{m 1} + {g}_{m 5} )} \qquad ( 23 )$$

If

$${ω}_{0} << \frac{( {g}_{m 1} + {g}_{m 5} )}{{C}_{L}}$$

does not hold, C_{IN} can be tuned out with off-chip matching network.

At impedance match (R_{IN}=R_{S}), the LNA voltage gain can be approximated as

$${A}_{V , LNA} = \vert \frac{{v}_{OUT}}{{v}_{IN}} \vert = \vert \frac{{v}_{OUT +} - {v}_{OUT -}}{{v}_{IN}} \vert \approx \frac{2}{{ω}_{0} {C}_{F} {R}_{S}} \qquad ( 24 )$$

Here, it is assumed that

$${ω}_{0} << \frac{2 ( {g}_{m 1} + {g}_{m 5} )}{{C}_{F}} .$$

Similarly, at impedance match, the differential LNA RF output current towards the mixers is

$${i}_{OUT} = {i}_{OUT +} - {i}_{OUT -} = {ω}_{0} {C}_{L} {v}_{OUT} = \frac{2 {C}_{L}}{{R}_{S} {C}_{F}} {v}_{IN} \qquad ( 25 )$$

based on which the LNA equivalent transconductance may be written as

$${G}_{m , LNA} = \frac{{i}_{OUT}}{{v}_{IN}} = \frac{2 {C}_{L}}{{R}_{S} {R}_{F}} \qquad ( 26 )$$

Thus, besides being a voltage amplifier, the SE2D CMOS CFB LNA 602 can be modelled as a transconductance amplifier, which converts the incoming single-ended RF voltage to the differential RF output current, which is driven to the current mode passive mixers.

The NF of the proposed SE2D CMOS CFB LNA can be written as

$$NF = 1 + \frac{γ}{{g}_{m 1} {R}_{S}} + \frac{γ {g}_{m 5}^{2}}{{{g}_{m 1} ( {g}_{m 1} + {g}_{m 5} )}^{2} {R}_{S}} + \frac{2 γ {g}_{m 3}}{{g}_{m 1}^{2} {R}_{S}} + \frac{γ {g}_{m 5}}{{( {g}_{m 1} + {g}_{m 5} )}^{2} {R}_{S}} \qquad ( 27 )$$

Here, the first term after ‘1’ is due to the first CS NMOS transistor M₁, the second term is due to the second (auxiliary) CS NMOS transistor M₂, the third term is due to the cross-coupled cascode of first and second cross-coupled cascode NMOS transistors M₃ & M₄ and the fourth term is due to the second (auxiliary) CS PMOS transistor M₆. Again, it is assumed that the excess noise coefficients of N- and PMOS transistors are equal, i.e., γ_{N}=γ_{P}=γ.

Similar to the SE2D CMOS RFB LNA 502 of FIGS. 5A and 5B, the noise due to the first CS PMOS transistor M₅ does not appear in (27). It can be shown that the noise due to M₅ appears as a common-mode noise voltage at the differential LNA output and is therefore cancelled. Thus, although the transistor M₅ contributes to the voltage-to-current amplification of the input signal, it does not contribute to the amplifier (differential) output noise. This is a clear benefit of the proposed SE2D CFB (and RFB) CMOS LNA 602.

Since the SE2D CFB CMOS LNA 602 does not include any resistors in its feedback, there is obviously no term associated with a feedback resistor in (27). As a result, the SE2D CFB LNA 602 may, in some cases, achieve lower NF compared to the NF of a corresponding SE2D RFB LNA.

It is concluded that the proposed SE2D CFB CMOS LNA 602 as shown in FIGS. 6A and 6B converts the single-ended input RF voltage to the differential RF output signal, which is available either in differential voltage or current through the LNA load capacitors. The SE2D CMOS CFB LNA 602 shares many of the benefits of the SE2D CMOS RFB LNA 502 of FIGS. 5A and 5B. Both N- and PMOS transistors are utilized also in the SE2D CMOS CFB LNA 602 which results in larger equivalent transconductance compared to using N- or PMOS transistors only. Finally, no on-chip inductors are employed in the SE2D CMOS CFB LNA 602, which results in low silicon area and cost.

Similar to as discussed for the SE2D CMOS RFB LNA above, in some cases, the SE2D CMOS RFB LNA 602 may need to drive a high-impedance capacitive load, instead of a low input impedance load presented by the current-mode passive IQ mixer 104. In such cases, a third load capacitor C_{L3} (equally called a differential load capacitor) may be connected (directly) between the negative and positive terminals of the differential output of the SE2D CMOS CFB LNA. The first and second load capacitor C_{L2} & C_{L1}, as discussed in connection with FIGS. 6A and 6B, may be omitted in such cases. FIG. 6C illustrates a SE2D CMOS CFB LNA 630 with such a modification (i.e., inclusion of the LNA load capacitor C_{L3} 631). Apart from the inclusion of the LNA load capacitor C_{L3} 631 (and possible omission of the first and second load capacitors C_{L2} & C_{L1}), the SE2D CMOS CFB LNA 630 of FIG. 6C may correspond to the SE2D CMOS CFB LNA 602 of FIGS. 6A and 6B.

In some embodiments, the SE2D CMOS CFB LNA 602 of FIG. 6B or the SE2D CMOS CFB LNA 630 of FIG. 6C may employ at least one off-chip impedance matching network or circuit.

While the embodiments have been discussed above mostly in connection with direct conversion radio receivers, the SE2D CMOS transconductance amplifiers and associated SE2D CMOS RFB/CFB LNAs according to embodiments may be suitable also for other types of radio receivers such as low-IF radio receivers.

While embodiments discussed above were based on CMOS transistors, in other embodiments, other transistor technologies may be employed for realizing single-ended-to-differential transconductance amplifier. Namely, in some embodiments, any of the embodiments described above may be implemented using bipolar junction transistors (BJT), instead of CMOS transistors.

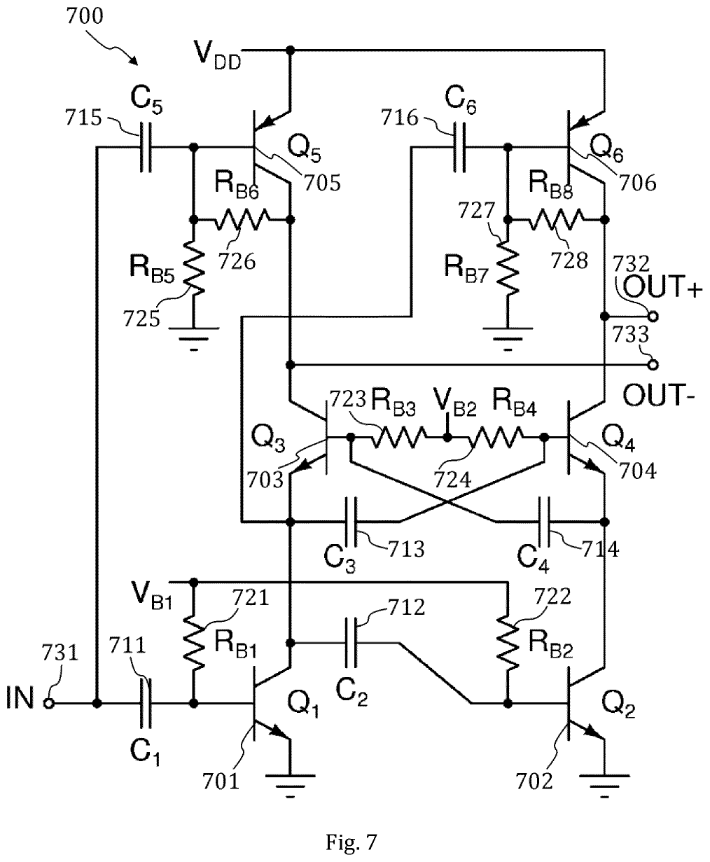

FIG. 7 shows a single-ended-to-differential bipolar junction transistor (SE2D BJT) transconductance amplifier 700 for a radio receiver according to embodiments. As can be observed from said Figure, the implementation (i.e., the arrangement of elements) corresponds, mutatis mutandis, to the CMOS implementation 200 of FIG. 2 with the only difference being that NPN/PNP transistors are employed instead of NMOS/PMOS transistors.

Referring to FIG. 7, the SE2D BJT transconductance amplifier 700 comprises at least:
an input 731 for receiving RF signal,
a first common-emitter (CE) NPN and CE PNP transistors Q₁ & Q₅ 701, 705,
second CE NPN and CE PNP transistors Q₂ & Q₆ 702, 706,
a cross-coupled cascode stage comprising first and second cross-coupled cascode NPN transistors Q₃ & Q₄ 703, 704 having substantially equal transconductances and
a differential output having a positive terminal 732 provided between the collectors of the second CE PNP transistor Q₆ 706 and the second cross-coupled cascode NPN transistor Q₄ 704 and a negative terminal 733 provided between the collectors of the first CE PNP transistor Q₅ 705 and the first cross-coupled cascode NPN transistor Q₃ 703.

Said elements of the SE2D BJT transconductance amplifier 700 are arranged, similar to FIG. 2, as follows:
a base of the first CE NPN transistor Q₁ 701 is coupled to the input directly or via a first capacitor C₁ 711,
a base of the first CE PNP transistor Q₅ 705 is coupled to the input directly or via a fifth capacitor C₅ 715,
a base of the second CE NPN transistor Q₂ 702 is coupled to a collector of the first CE NPN transistor Q₁ 701 directly or via a second capacitor C₂ 712,
a base of the second CE PNP transistor Q₆ 706 is coupled to the collector of the first CE NPN transistor Q₁ 701 directly or via a sixth capacitor C₆ 716,
a collector of the first cross-coupled cascode NPN transistor Q₃ 703 is coupled directly to a collector of the first CE PNP transistor Q₅ 705,
an emitter of the first cross-coupled cascode NPN transistor Q₃ 703 is coupled directly to the collector of the first CE NPN transistor Q₁ 701,
a base of the first cross-coupled cascode NPN transistor Q₃ 703 is coupled via a fourth capacitor C₄ 714 to an emitter of the second cross-coupled cascode NPN transistor Q₄ 704,
a collector of the second cross-coupled cascode NPN transistor Q₄ 704 is coupled directly to a collector of the second CE PNP transistor Q₆ 706,
an emitter of the second cross-coupled cascode NPN transistor Q₄ 704 is coupled directly to a collector of the second CE NPN transistor Q₂ 702 and
a base of the second cross-coupled cascode NPN transistor is coupled via a third capacitor C₃ 713 to an emitter of the first cross-coupled cascode NPN transistor Q₃ 703.

The first and second CE NPN transistors Q₁ & Q₂ 701, 702 have (substantially) equal transconductances and the first and second CE PNP transistors Q₅ & Q₆ 705, 706 have (substantially) equal transconductances.

Additionally, emitters of the first and second CE NPN transistors Q₁ & Q₂ 701, 702 may be grounded and sources of the first and second CE PNP transistors Q₅ & Q₆ 705, 706 may be connected to a positive supply voltage input (V_{DD}), as shown in FIG. 7.

Any of the other definitions provided for the CMOS-based embodiments discussed in connection with FIGS. 2, 3, 4A and 4B may apply, mutatis mutandis, for the BJT-based implementation. Elements 711-716, 721-728 and 731-733 of FIG. 7 may correspond fully to elements 211-216, 221-228 and 231-233 of FIG. 2, respectively.

In some embodiments, a SE2D resistive-feedback or capacitive-feedback BJT LNA comprising the SE2D BJT transconductance amplifier 700 may be provided. The SE2D resistive-feedback BJT LNA may correspond to the SE2D resistive-feedback CMOS LNA as discussed in connection with FIGS. 5A, 5B and 5C with the change that the SE2D CMOS transconductance amplifier 503 has been replaced with the SE2D BJT transconductance amplifier 700. The SE2D capacitive-feedback BJT LNA may correspond to the SE2D capacitive-feedback CMOS LNA as discussed in connection with FIGS. 6A, 6B and 6C with the change that the SE2D CMOS transconductance amplifier 603 has been replaced with the SE2D BJT transconductance amplifier 700. In some alternative embodiments, the SE2D CMOS transconductance amplifier may be implemented using NMOS transistors, instead of PMOS transistors, and PMOS transistor, instead of NMOS transistors. In other words, the polarity of the transistors of the SE2D CMOS transconductance amplifier may be switched compared to the SE2D CMOS transconductance amplifier discussed above. Similarly, the SE2D BJT transconductance amplifier may be implemented, in some embodiments, using NPN transistors, instead of PNP transistors, and PNP transistor, instead of NPN transistors.

As used in this application, the term ‘circuit’ or ‘circuitry’ refers to one or more of the following: hardware-only circuit implementations such as implementations in only analogue and/or digital circuitry; combinations of hardware circuits and software and/or firmware; and circuits such as a microprocessor(s) or a portion of a microprocessor(s) that require software or firmware for operation, even if the software or firmware is not physically present. This definition of ‘circuit’ applies to uses of this term in this application. The term “circuit” would also cover, for example and if applicable to the particular element, a baseband integrated circuit, an application-specific integrated circuit (ASIC), and/or a field-programmable grid array (FPGA) circuit for the apparatus according to an embodiment of the invention.

Embodiments described herein are applicable to systems defined above but also to other systems. The specifications of the systems and their elements develop rapidly. Such development may require extra changes to the described embodiments. Therefore, all words and expressions should be interpreted broadly and they are intended to illustrate, not to restrict, the embodiment. It will be obvious to a person skilled in the art that, as technology advances, the inventive concept can be implemented in various ways. Embodiments are not limited to the examples described above but may vary within the scope of the claims.

1. A single-ended-to-differential complementary metal oxide-semiconductor, SE2D CMOS, transconductance amplifier for a radio receiver, the SE2D CMOS transconductance amplifier comprising:
an input for receiving a radio frequency, RF, signal;
first common-source n-type metal-oxide-semiconductor, CS NMOS, and common-source p-type metal-oxide semiconductor, CS PMOS, transistors, wherein
a gate of the first CS NMOS transistor is coupled to the input directly or via a first capacitor and
a gate of the first CS PMOS transistor is coupled to the input directly or via a fifth capacitor;
second CS NMOS and CS PMOS transistors, wherein
a gate of the second CS NMOS transistor is coupled to a drain of the first CS NMOS transistor directly or via a second capacitor,
a gate of the second CS PMOS transistor is coupled to the drain of the first CS NMOS transistor directly or via a sixth capacitor,
the first and second CS NMOS transistors have substantially equal transconductances and
the first and second CS PMOS transistors have substantially equal transconductances;
a cross-coupled cascode stage comprising first and second cross-coupled cascode NMOS transistors having substantially equal transconductances, wherein a drain of the first cross-coupled cascode NMOS transistor is coupled directly to a drain of the first CS PMOS transistor,
a source of the first cross-coupled cascode NMOS transistor is coupled directly to the drain of the first CS NMOS transistor,
a gate of the first cross-coupled cascode NMOS transistor is coupled via a fourth capacitor to a source of the second cross-coupled cascode NMOS transistor,
a drain of the second cross-coupled cascode NMOS transistor is coupled directly to a drain of the second CS PMOS transistor,
a source of the second cross-coupled cascode NMOS transistor is coupled directly to a drain of the second CS NMOS transistor and
a gate of the second cross-coupled cascode NMOS transistor is coupled via a third capacitor to a source of the first cross-coupled cascode NMOS transistor; and
a differential output having a positive terminal provided between the drains of the second CS PMOS transistor and the second cross-coupled cascode NMOS transistor and a negative terminal provided between the drains of the first CS PMOS transistor and the first cross-coupled cascode NMOS transistor.

2. The SE2D CMOS transconductance amplifier of claim 1, wherein the SE2D CMOS transconductance amplifier is configured to satisfy the following:
the gate of the first CS NMOS transistor is coupled to the input via the first capacitor;
the gate of the first CS PMOS transistor is coupled to the input via the fifth capacitor;
the gate of the second CS NMOS transistor is coupled to the drain of the first CS NMOS transistor via the second capacitor; and
the gate of the second CS PMOS transistor is coupled to the drain of the first CS NMOS transistor via the sixth capacitor.

3. The SE2D CMOS transconductance amplifier according to claim 1, wherein the SE2D CMOS transconductance amplifier is configured to satisfy one or more of the following:
sources of the first and second CS NMOS transistors are grounded; and
sources of the first and second CS PMOS transistors are connected to a positive supply voltage input.

4. The SE2D CMOS transconductance amplifier according to claim 1, further comprising:
biasing means for biasing the first and second CS NMOS transistors, the first and second CS PMOS transistors and the first and second cross-coupled cascode NMOS transistors.

5. The SE2D CMOS transconductance amplifier according to claim 4, wherein the biasing means comprise:
one or more biasing voltage inputs for receiving one or more biasing voltages for biasing the first and second CS NMOS transistors, the first and second CS PMOS transistors and the first and second cross-coupled cascode NMOS transistors; and/or
one or more capacitors for blocking biasing currents, the one or more capacitors comprising one or more of the first, second, third, fourth, fifth and sixth capacitors; and/or
one or more isolating resistors for isolating the one or more biasing voltage inputs from radio frequency signal paths.

6. The SE2D CMOS transconductance amplifier according to claim 4, wherein the biasing means comprise:
one or more biasing resistors for adjusting DC biasing voltages applied to one or more terminals of the first and second CS NMOS transistors, the first and second CS PMOS transistors and the first and second cross-coupled cascode NMOS transistors.

7. The SE2D CMOS transconductance amplifier according to claim 4, wherein the biasing means further comprise:
one or more bias current mirrors formed between at least one diode-connected transistor and two or more of the first and second CS NMOS transistors, the first and second CS PMOS transistors and the first and second cross-coupled cascode NMOS transistors for copying bias currents.

8. The SE2D CMOS transconductance amplifier according to claim 1, wherein the SE2D CMOS transconductance amplifier comprises no inductors.

9. A SE2D capacitive-feedback CMOS low-noise amplifier, LNA, comprising:
a SE2D CMOS transconductance amplifier according to claim 1;
a feedback capacitor connected between the negative terminal of the differential output and the input of the SE2D CMOS transconductance amplifier; and
first and second load capacitors connected to the positive and negative terminals of the differential output of the SE2D CMOS transconductance amplifier and/or a third load capacitor connected between the positive and negative terminals of the differential output of the SE2D CMOS transconductance amplifier.

10. The SE2D capacitive-feedback CMOS LNA of claim 9, further comprising:
a balancing capacitor connected between the positive terminal of the differential output of the SE2D CMOS transconductance amplifier and the ground.

11. The SE2D capacitive-feedback CMOS LNA of claim 10, wherein a capacitance of the balancing capacitor is equal to a capacitance of the feedback capacitor.

12. The SE2D capacitive-feedback CMOS LNA according to claim 9, wherein capacitances of the first and second load capacitors are equal.

13. A SE2D resistive-feedback CMOS low-noise amplifier, LNA, comprising:
a SE2D CMOS transconductance amplifier according to claim 1;
a feedback resistor;
a feedback capacitor connected in series with the feedback resistor so as to form a first series circuit, wherein the first series circuit is connected between the negative terminal of the differential output and the input of the SE2D CMOS transconductance amplifier; and
first and second load resistors connected to the positive and negative terminals of the differential output of the SE2D CMOS transconductance amplifier and/or a third load resistor connected between the positive and negative terminals of the differential output of the SE2D CMOS transconductance amplifier.

14. The SE2D resistive-feedback CMOS LNA of claim 13, further comprising:
a capacitor;
a resistor connected in series with the capacitor so as to form a second series circuit, wherein the second series circuit is connected between the positive terminal of the differential output of the SE2D CMOS transconductance amplifier and the ground.

15. The SE2D resistive-feedback CMOS LNA of claim 14, wherein a resistance of the resistor of the second series circuit is equal to a resistance of the feedback resistor.

16. The SE2D resistive-feedback CMOS LNA according to claim 13, wherein resistances of the first and second load resistors are equal.

17. A single-ended-to-differential bipolar junction transistor, SE2D BJT, transconductance amplifier for a radio receiver, the SE2D BJT transconductance amplifier comprising:
an input for receiving a radio frequency, RF, signal;
first common-emitter, CE, NPN and CE PNP transistors, wherein
a base of the first CE NPN transistor is coupled to the input directly or via a first capacitor and
a base of the first CE PNP transistor is coupled to the input directly or via a fifth capacitor;
second CE NPN and CE PNP transistors, wherein
a base of the second CE NPN transistor is coupled to a collector of the first CE NPN transistor directly or via a second capacitor,
a base of the second CE PNP transistor is coupled to the collector of the first CE NPN transistor directly or via a sixth capacitor,
the first and second CE NPN transistors have substantially equal transconductances and
the first and second CE PNP transistors have substantially equal transconductances;
a cross-coupled cascode stage comprising first and second cross-coupled cascode NPN transistors having substantially equal transconductances, wherein a collector of the first cross-coupled cascode NPN transistor is coupled directly to a collector of the first CE PNP transistor,
an emitter of the first cross-coupled cascode NPN transistor is coupled directly to the collector of the first CE NPN transistor,
a base of the first cross-coupled cascode NPN transistor is coupled via a fourth capacitor to an emitter of the second cross-coupled cascode NPN transistor,
a collector of the second cross-coupled cascode NPN transistor is coupled directly to a collector of the second CE PNP transistor,
an emitter of the second cross-coupled cascode NPN transistor is coupled directly to a collector of the second CE NPN transistor and
a base of the second cross-coupled cascode NPN transistor is coupled via a third capacitor to an emitter of the first cross-coupled cascode NPN transistor; and
a differential output having a positive terminal provided between the collectors of the second CE PNP transistor and the second cross-coupled cascode NPN transistor and a negative terminal provided between the collectors of the first CE PNP transistor and the first cross-coupled cascode NPN transistor.

18. A radio receiver comprising:
a single-ended low-noise amplifier and one of a SE2D CMOS transconductance amplifier according to claim 1 and a SE2D BJT transconductance amplifier of claim 17 connected to the single-ended low-noise amplifier; or
a SE2D capacitive-feedback CMOS LNA; or
a SE2D resistive-feedback CMOS LNA.

19. The radio receiver of claim 18, wherein the radio receiver is a direct conversion radio receiver.
